(19) United States
(12) Patent Application Publication
(10) Pub. No.: US 2026/0123531 A1
(43) Pub. Date: Apr. 30, 2026

(54) ONE-WIRE INTERFACE TO SUPPORT SHARING A LOSS OF SIGNAL EVENT

(71) Applicant: MACOM Technology Solutions Holdings, Inc., Lowell, MA (US)

(72) Inventor: MIKHAIL BARASHENKA, Lowell, MA (US)

(21) Appl. No.: 18/933,884

(22) Filed: Oct. 31, 2024

(51) Int. Cl. H01L 25/16

(52) U.S. Cl. CPC H10W 90/00

(57) ABSTRACT

Circuits, semiconductor devices, and systems are provided. An illustrative system includes a semiconductor package having a photodiode to receive a light signal and convert the light signal into an electrical signal, an Integrated Circuit (IC) chip coupled with the photodiode, where the IC chip receives the electrical signal from the photodiode and transfers the electrical signal to components supporting high-speed communications in an electrical domain, and a one-wire interface that connects the IC chip with an external processor. The system may further include an external processor that exchanges data with the IC chip via the one-wire interface and that receives information regarding a state of the light signal from the IC chip via the one-wire interface.

### FIELD OF THE DISCLOSURE

The present disclosure is generally directed toward circuits and, in particular, toward circuit packages used in high-speed communications.

### BACKGROUND

High-speed communication systems are constantly improving. As data rates increase, the requirements of components in the system are pushed to their physical limits. Meanwhile, a desire exists to control the cost of components in the system and/or to reduce the overall size of the components in the system. The desire for increased data rates and other performance demands is often in direct contradiction with the desire to reduce the cost of the system and/or the size of the system.

As an example, there are certain components in a communication system that have a fixed number of inputs and/or outputs (e.g., pins). The physical limitation of the number of pins made available to a component can often limit the component's functional capabilities without intent.

### SUMMARY

Embodiments of the present disclosure contemplate solutions to the above-noted challenges. In particular, a one-wire interface is provided to enable the exchange of multiple different types of data between components in a high-speed communication system. In some embodiments, the one-wire interface facilitates two-way exchange of data between a chip on a first package and an external processor. The one-wire interface further facilitates an exchange of a Loss of Signal (LOS) indication from the chip on the first package to the external processor.

In some embodiments, a LOS indication is shared via a LOS signal which is transmitted over the one-wire interface. For certain types of packaging, the number of pins provided in the packaging may be limited. It becomes desirable to use the limited number of pins such that important chip statement indicators can be transferred outside of the first package (e.g., for processing by an external processor). During the use of a one-wire interface, a variable terminal voltage can be implemented for a pullup resistor. Utilizing a variable terminal voltage on the one-wire interface can help provide different logical indicators with different voltages. For instance, the difference between voltages on the one-wire interface can indicate two different states. In some examples, during normal processing, a first voltage level (e.g., a 1.8V level) can be used to represent a logical “1” for the exchange of data over the one-wire interface. Meanwhile, if a LOS event occurs, then the LOS indicator can be shared by applying a second voltage level (e.g., a 3.3V level) over the same one-wire interface to indicate a logical “1” for the LOS event. In this way, the one-wire interface can be used to communicate data with the external package and then further communicate an LOS event, when such an event occurs.

According to at least some embodiments of the present disclosure, a system is provided that includes: a semiconductor package having a photodiode to receive a light signal and convert the light signal into an electrical signal, an Integrated Circuit (IC) chip coupled with the photodiode, where the IC chip receives the electrical signal from the photodiode and transfers the electrical signal to components supporting high-speed communications in an electrical domain, and a one-wire interface that connects the IC chip with an external processor. The system may further include an external processor that exchanges data with the IC chip via the one-wire interface and that receives information regarding a state of the light signal from the IC chip via the one-wire interface

In some embodiments, a semiconductor device is provided that includes: a photodiode to receive a light signal and convert the light signal into an electrical signal; an IC chip coupled with the photodiode, where the IC chip receives the electrical signal from the photodiode and transfers the electrical signal to components supporting high-speed communications in an electrical domain; and a one-wire interface that connects the IC chip with an external processor, where the one-wire interface enables the IC chip to receive data from the external processor and to communicate information regarding a state of the light signal to the external processor.

In some embodiments, a semiconductor device is provided that includes: an IC chip coupled with a photodiode, where the IC chip receives an electrical signal from the photodiode and transfers the electrical signal to components supporting high-speed communications in an electrical domain; and a one-wire interface that connects the IC chip with an external processor, where the one-wire interface enables the IC chip to receive data from the external processor and to communicate a Loss of Signal (LOS) indication to the external processor.

According to at least some embodiments, the circuit, semiconductor device, and/or system may further include additional circuitry (e.g., one or more circuits) to support the operations of the one-wire interface. Such circuits may include components on a semiconductor device or package and/or components on an external processor. The circuit may include components solely on the semiconductor device or package or components solely on the external processor.

The preceding is a simplified summary to provide a basic understanding of some aspects and embodiments described herein. This summary is not an extensive overview of the disclosed subject matter. It is neither intended to identify key nor critical elements of the disclosure nor delineate the scope thereof. The summary is provided to present some concepts in a simplified form as a prelude to the more detailed description that is presented later.

### BRIEF DESCRIPTION OF THE DRAWINGS

The present disclosure is described in conjunction with the appended figures, which are not necessarily drawn to scale:

FIG. 1 is a block diagram illustrating components of a high-speed communication system according to at least some embodiments of the present disclosure;

FIG. 2 is a block diagram illustrating a circuit according to at least some embodiments of the present disclosure; and

FIG. 3 illustrates a method of operating a high-speed communication system according to at least some embodiments of the present disclosure.

### DETAILED DESCRIPTION

It is with respect to the above-noted challenges that embodiments of the present disclosure were contemplated. In particular, a system, circuits, and method of operating such circuits are provided that solve the drawbacks associated with existing semiconductor packages.

While embodiments of the present disclosure will primarily be described in connection with circuits used in high-speed communication applications (e.g., high-bandwidth applications in which communications are exchanged at 10 MHz, 100 MHz, 1 GHz, or more), it should be appreciated that embodiments of the present disclosure are not so limited. Furthermore, while embodiments of the present disclosure are contemplated for use in connection with high-speed communications over copper or fiber, it should be appreciated that the claims are not limited to high speed electrical and optical or electro-optical (EO) communications. Indeed, the one-wire interface depicted and described herein may be utilized in any number of applications in which it is desirable to utilize a single wire or single Input/Output (I/O) pin to exchange multiple different data signals. Example embodiments of the present disclosure will be described in connection with broadband applications, but it should be appreciated that the circuit(s) depicted and described herein can be utilized in other non-broadband applications.

Various aspects of the present disclosure will be described herein with reference to drawings that are schematic illustrations of idealized configurations. It should be appreciated that while particular circuit configurations and circuit elements are described herein, embodiments of the present disclosure are not limited to the illustrative circuit configurations and/or circuit elements depicted and described herein. Specifically, it should be appreciated that circuit elements of a particular type or function may be replaced with one or multiple other circuit elements to achieve a similar function without departing from the scope of the present disclosure.

It should also be appreciated that the embodiments described herein may be implemented in any number of form factors. Specifically, the entirety of the circuits disclosed herein may be implemented in silicon as a fully-integrated solution (e.g., as a single Integrated Circuit (IC) chip or multiple IC chips) or they may be implemented as discrete components connected to a Printed Circuit Board (PCB). For example, circuit components depicted and described herein may be provided on a single piece of silicon (e.g., a single semiconductor die), on multiple pieces of silicon, on a PCB, across multiple packages, or combinations thereof.

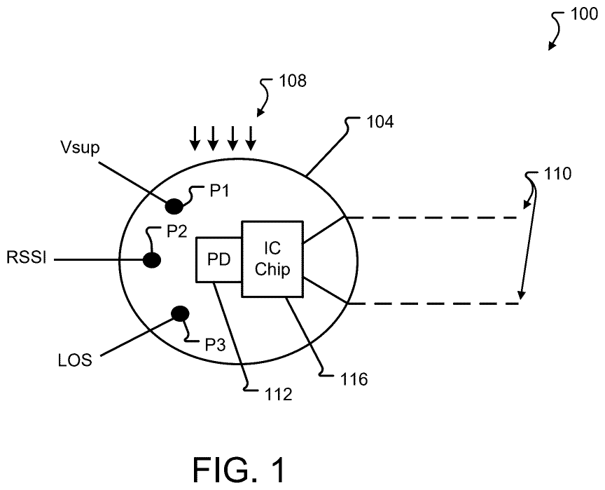

Referring initially to FIG. 1, components of an illustrative high-speed communication system 100 will be described in accordance with at least some embodiments of the present disclosure. The system 100 represents but one possible environment of use of the innovation(s) disclosed herein. As shown, the system 100 may include a semiconductor device or semiconductor package 104 configured to support high-speed or high-bandwidth communications. The semiconductor package 104 may be configured to receive an optical signal 108 and convert the optical signal 108 into an electrical signal that is exchanged with other components supporting high-speed communications in an electrical domain. More specifically, the optical signal 108 may be received from an end of a fiber optic cable at a photodiode 112. The photodiode 112 may be configured to convert the optical signal 108 into an electrical signal.

An output of the photodiode 112 may be provided to one or more circuit components within the IC chip 116. For instance, the IC chip 116 may include one or more amplifiers (e.g., Transimpedance Amplifiers), one or more passive circuit elements (e.g., resistors, capacitors, inductors, etc.), and/or one or more active circuit elements (e.g., transistors, switches, diodes, etc.). The components of the IC chip 116 may receive the electrical signal from the photodiode 112 and, after processing the electrical signal, place the electrical signal onto a high-speed data output 110. Signals communicated on the high-speed data output 110 may be transmitted at a high frequency, such as above 10 MHz, 100 MHz, 1 GHz, or more.

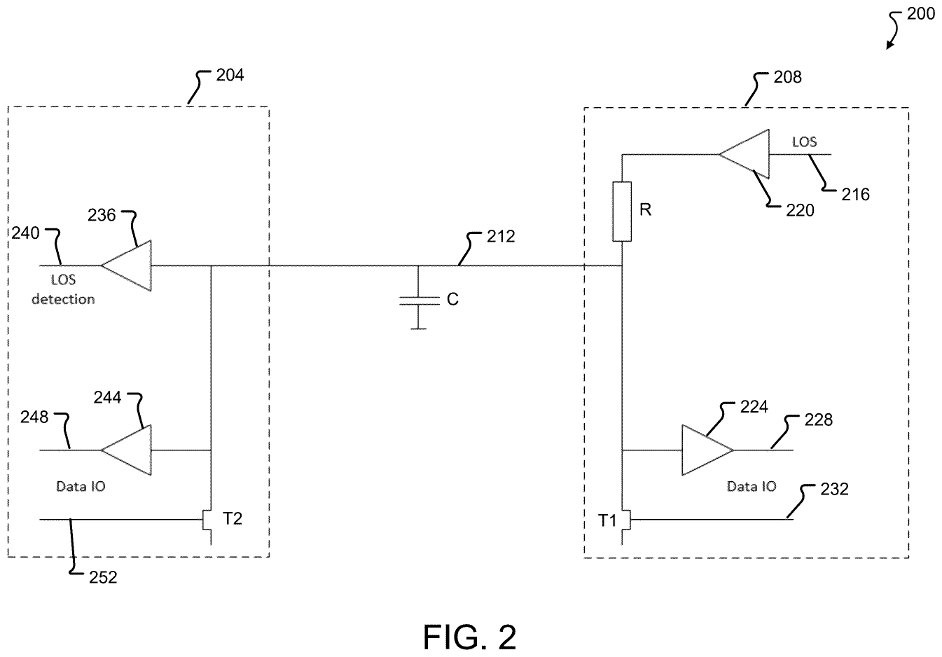

Components of the semiconductor package 104 may also be configured to connect with an external processor to support operations of the semiconductor package 104. For instance, the IC chip 116 may receive a supply voltage (Vsup) from a first pin P1. The IC chip 116 may also be configured to exchange Received Signal Strength Indications (RSSI) via a second pin P2. The IC chip 116 may also have a third pin P3 that provides a one-wire interface with an external processor 204 as shown in FIG. 2. More specifically, the third pin P3 may be used to support two-way data exchanges between the semiconductor package 104 and the external processor 204. The third pin P3 may also support the sharing of a LOS indication from the IC chip 116 to the external processor 204. Although not shown in FIG. 1, it should be appreciated that each pin P1, P2, and P3 may be electrically coupled with the IC chip 116 via one or more wires, wire bonds, and/or traces that pass through the body of the semiconductor package 104. Alternatively or additionally, the semiconductor package 104 may include one or more substrates or PCBs with one or more traces, electrically-conductive vias, or the like, that electrically connect the pins P1, P2, and P3 to the IC chip 116.

With further reference to FIG. 2, a circuit 200 is shown in which components of the IC chip 208 are enabled to communicate with components of an external processor 204 via a one-wire interface 212. As noted above in connection with FIG. 1, the one-wire interface 212 may be supported by a single pin, such as the third pin P3. The one-wire interface 212 may include an inherent capacitance C, which may depend upon the material used for the one-wire interface 212 and/or the length of the one-wire interface. In some embodiments, the capacitance C of the one-wire interface 212 may be on the order of a 10 pF to 100 pF.

The components of the IC chip 208 are shown to include an amplifier 220, a pull-up resistor R, and a first comparator 224. The amplifier 220 may receive an LOS signal from within the IC chip 116, which indicates that the photodiode 112 is no longer receiving the light signal 108. Alternatively or additionally, the LOS signal received from the IC chip 116 may indicate that less than a required amount of the light signal 108 is reaching the photodiode 112. In some embodiments, an LOS signal received at the LOS input 216 may indicate that the photodiode 112 is out of alignment with the fiber optic providing the light signal 108.

The LOS signal received at the amplifier 220 may be amplified to a predetermined voltage level and passed through the pull-up resistor R. The output side of the pull-up resistor R may be attached to the one-wire interface 212, which also represents a shared node between the first comparator 224 as well as two other comparators on the external processor 204 (e.g., a second comparator 236 and a third comparator 244). The pull-up resistor may have a resistance on the order of 1 kOhm to 10 kOhm.

In some embodiments, a variable termination voltage can be implemented for the pull-up resistor R such that a different in the voltages applied across the pull-up resistor indicate an LOS event and/or indicate an absence of an LOS event. In the absence of an LOS event (e.g., during normal operations), the one-wire interface 212 can be used to support data communications between the external processor 204 and the IC chip 116. Specifically, but without limitation, during normal operations (e.g., in an absence of an LOS indication on the one-wire interface 212), the one-wire interface 212 can be used to facilitate an exchange of commands between the external processor 204 and the IC chip 116. Through the one-wire interface 212, access to registers of the IC chip 116 are made available to support setting changes or adjustments to one or more operating parameters for the IC chip 116. Examples of setting changes or operating parameter adjustments that may be made to the IC chip 116 via the one-wire interface 212 include, without limitation, bandwidth adjustments, internal current settings, linearity settings, and the like.

In some embodiments, the one-wire interface 212 may correspond to a relatively slow interface as compared to the high-speed data output 110. Specifically, the one-wire interface 212 may support communications using a frequency of approximately 9.6 kHz to 10 kHz as compared to the much higher frequencies supported by the high-speed data output 110. The exchange of data via the one-wire interface 212 during normal operations (e.g., in an absence of an LOS event) may be facilitated by one or more transistors T1, T2, which are connected to control inputs 232, 252 respectively, as well as the first comparator 224 and the third comparator 244.

In some embodiments, data communications between the IC chip 116 and the external processor 204 may utilize a first data I/O 228 and a second data I/O 248, which are outputs of the first comparator 224 and third comparator 244, respectively. Communication of the LOS indications may be carried out using the second comparator 236, which is connected to an LOS detection line 240. The second comparator 236 may compare voltage on the one-wire interface 212 with a first voltage threshold whereas the first comparator 224 and third comparator 244 may compare the voltage on the one-wire interface 212 with a second voltage threshold.

In some embodiments, the first voltage threshold is greater than the second voltage threshold. In other words, the second comparator 236 may output a predetermined logical value (e.g., logical “1”) to represent a positive determination of a LOS indication on the one-wire interface 212 when the voltage on the one-wire interface 212 exceeds the first voltage threshold. As an example, the first voltage threshold may correspond to a value of approximately 2.0V, 2.5V, 3.0V, or 3.5V. Alternatively or additionally, the second comparator 236 may output the predetermined logical value representative of the LOS indication when the voltage on the one-wire interface 212 substantially matches (e.g., within a predetermined amount) the first voltage threshold.

Continuing the above example, the first comparator 224 and third comparator 244 may output a predetermined logical value (e.g., a logical “1”) representing a data signal on the one-wire interface 212 when the voltage on the one wire-interface exceeds the second voltage threshold, but not the first voltage threshold. As an example, the second voltage threshold may correspond to a value of approximately 0.5V, 0.9V, 1.0V, or 1.5V. Alternatively or additionally, the first comparator 224 and third comparator 244 may output the predetermined logical value representative of a data exchange when the voltage on the one-wire interface 212 substantially matches (e.g., within a predetermined amount) the second voltage threshold. In some embodiments, the first voltage threshold (e.g., the comparison applied by the second comparator 236) may be at least twice as large as the second voltage threshold (e.g., the comparison applied by the first comparator 224 and third comparator 244) so as to provide a large enough buffer between the first voltage threshold and the second voltage threshold (e.g., to avoid confusion between exchanges of data on the one-wire interface 212 as compared to exchanges of LOS indications on the one-wire interface 212).

In normal operations (e.g., in an absence of an LOS event), data may be communicated bidirectionally between the IC chip 116 and the external processor 204 using the transistors T1, T2. Specifically, and without limitation, the transistors T1, T2 may be controlled using control inputs 232, 252, respectively, to send data over the one-wire interface 212. As an example, the external processor 204 may communicate data to the IC chip 116 by manipulating the control input 252 applied to the second transistor T2. The first comparator 224 may detect changes in voltage (e.g., between zero volts and the second voltage threshold) on the one-wire interface 212, to receive the data transmitted by the external processor 204. Conversely, the IC chip 116 may manipulate the control input 232 applied to the first transistor T1 to communicate data to the external processor 204 via the one-wire interface 212. The third comparator 244 may detect changes in voltage (e.g., between zero volts and the second voltage threshold) on the one-wire interface 212, to receive data transmitted by the IC chip 116.

The external processor 204 may correspond to any suitable type of processing unit or device. Non-limiting examples of an external processor 204 may include a Central Processing Unit (CPU), a Graphics Processing Unit (GPU), a Data Processing Unit (DPU), a microprocessor, a collection of microprocessors, an IC chip, a collection of IC chips, an Application Specific Integrated Circuit (ASIC), or the like. In other words, the external processor 204 may correspond to one or many different types of processing units or devices without departing from the scope of the present disclosure.

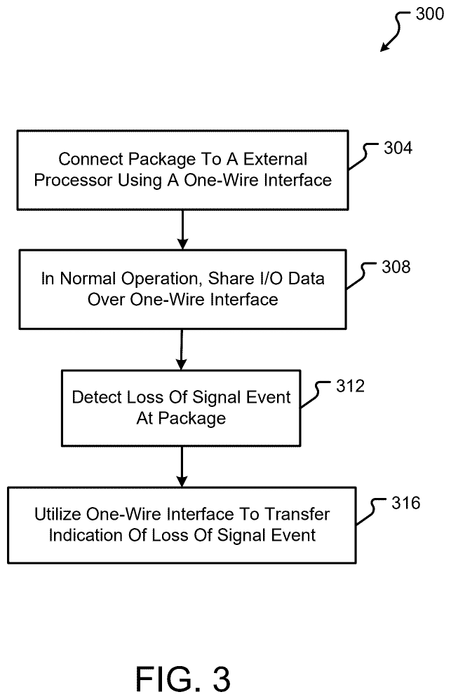

Referring now to FIG. 3, a method 300 will be described in accordance with at least some embodiments of the present disclosure. The method 300 begins by connecting a semiconductor package 104 to an external processor 204 using a one-wire interface (step 304).

The method 300 continues by enabling an exchange of data over the one-wire interface 212 (step 308). For instance, data may be exchanged between the external processor 204 and an IC chip 116 within the semiconductor package 104 using the one-wire interface 212. In some embodiments, the exchange of data between the external processor 204 and the IC chip 116 may correspond to a bidirectional exchange of data. As noted above, the exchange of data may utilize a voltage level on the one-wire interface 212 that is different from a voltage level used to communicate an LOS indication on the one-wire interface 212.

In some embodiments, the method 300 may continue when an LOS event is detected at the semiconductor package 104 (step 312). For example, the LOS event may be detected when the photodiode 112 is misaligned with respect to a light source providing the light signal 108. As another example, the LOS event may be detected when a strength of the light signal 108 received at the photodiode 112 is less than a threshold strength, meaning that the light signal 108 is insufficient to produce an appropriate electrical signal on the high-speed data output 110. As another example, the LOS event may be detected when the photodiode 112 is not detecting any light signal 108.

When the LOS event is detected, the method 300 may continue by transferring information regarding a state of the light signal, such as an indication of the LOS event (e.g., via an LOS indication or LOS signal), from the semiconductor package 104 to the external processor 204 using the one-wire interface 212 (step 316). As noted above, a voltage threshold used for communicating the LOS indication may be greater than the voltage threshold used to exchange data between the semiconductor package 104 and the external processor 204.

Specific details were given in the description to provide a thorough understanding of the embodiments. However, it will be understood by one of ordinary skill in the art that the embodiments may be practiced without these specific details. In other instances, well-known circuits, processes, algorithms, structures, and techniques may be shown without unnecessary detail in order to avoid obscuring the embodiments.

While illustrative embodiments of the disclosure have been described in detail herein, it is to be understood that the inventive concepts may be otherwise variously embodied and employed, and that the appended claims are intended to be construed to include such variations, except as limited by the prior art.

What is claimed is:

1. A system, comprising:
a semiconductor package, comprising:
a photodiode to receive a light signal and convert the light signal into an electrical signal;
an Integrated Circuit (IC) chip coupled with the photodiode, wherein the IC chip receives the electrical signal from the photodiode and transfers the electrical signal to components supporting high-speed communications in an electrical domain; and
a one-wire interface that connects the IC chip with an external processor; and
an external processor that exchanges data with the IC chip via the one-wire interface and that receives information regarding a state of the light signal from the IC chip via the one-wire interface.

2. The system of claim 1, wherein the external processor uses a first voltage threshold to receive the information regarding the state of the light signal and wherein the external processor exchanges data with the IC chip via the one-wire interface using a second voltage threshold.

3. The system of claim 2, wherein the first voltage threshold is greater than the second voltage threshold.

4. The system of claim 3, wherein the external processor comprises a first comparator to apply the first voltage threshold and wherein the external processor comprises a second comparator to apply the second voltage threshold.

5. The system of claim 1, wherein the information regarding the state of the light signal provides an indication as to whether or not the photodiode is receiving the light signal.

6. The system of claim 1, wherein the information regarding the state of the light signal includes a Loss of Signal (LOS) indication.

7. The system of claim 1, wherein the information regarding the state of the light signal provides an indication as to whether or not the photodiode is aligned with a light source.

8. The system of claim 1, wherein the external processor provides one or more commands to the IC chip via the one-wire interface.

9. The system of claim 8, wherein the one or more commands comprise an instruction to adjust an operating parameter of the IC chip.

10. The system of claim 1, wherein a pull-up resistor is provided between an amplifier in the IC chip and the external processor to support an exchange of the information regarding the state of the light signal.

11. A semiconductor device, comprising:
a photodiode to receive a light signal and convert the light signal into an electrical signal;
an Integrated Circuit (IC) chip coupled with the photodiode, wherein the IC chip receives the electrical signal from the photodiode and transfers the electrical signal to components supporting high-speed communications in an electrical domain; and
a one-wire interface that connects the IC chip with an external processor, wherein the one-wire interface enables the IC chip to receive data from the external processor and to communicate information regarding a state of the light signal to the external processor.

12. The semiconductor device of claim 11, wherein the data received from the external processor via the one-wire interface comprises one or more instructions to adjust an operating parameter of the IC chip.

13. The semiconductor device of claim 11, wherein a first voltage threshold is used to determine an existence of the information regarding the state of the light signal and wherein a second voltage threshold is used to determine an existence of data on the one-wire interface.

14. The semiconductor device of claim 11, wherein the information regarding the state of the light signal includes a Loss of Signal (LOS) indication.

15. The semiconductor device of claim 11, wherein the one-wire interface is connected with the IC chip via a single Input/Output (I/O) pin.

16. The semiconductor device of claim 15, further comprising:
a second I/O pin to receive a supply voltage; and
a third I/O pin to exchange a Received Signal Strength Indicator (RSSI) signal.

17. The semiconductor device of claim 11, further comprising a pull-up resistor positioned between an amplifier providing the information regarding the state of the light signal and the one-wire interface.

18. A semiconductor device, comprising:
an Integrated Circuit (IC) chip coupled with a photodiode, wherein the IC chip receives an electrical signal from the photodiode and transfers the electrical signal to components supporting high-speed communications in an electrical domain; and
a one-wire interface that connects the IC chip with an external processor, wherein the one-wire interface enables the IC chip to receive data from the external processor and to communicate a Loss of Signal (LOS) indication to the external processor.

19. The semiconductor device of claim 18, wherein the data received from the external processor via the one-wire interface comprises one or more instructions to adjust an operating parameter of the IC chip, wherein a first voltage threshold is used to communicate the LOS indication and wherein a second voltage threshold is used to determine an existence of data on the one-wire interface.

20. The semiconductor device of claim 19, wherein the one-wire interface is connected with the IC chip via a single input/output (I/O) pin.
